(19) United States
(12) Patent Application Publication
(10) Pub. No.: US 2022/0180911 A1
(43) Pub. Date: Jun. 9, 2022

(54) EXTERNAL MAGNETIC BOTTOM CONTACT STRUCTURE FOR MRAM

(71) Applicant: INTERNATIONAL BUSINESS MACHINES CORPORATION, ARMONK, NY (US)

(72) Inventors: Saba Zare, Albany, NY (US); Michael Rizzolo, Delmar, NY (US); Virat Vasav Mehta, Albany, NY (US); Eric Raymond Evarts, Niskayuna, NY (US); Theodorus E. Standaert, Clifton Park, NY (US)

(21) Appl. No.: 17/247,306

(22) Filed: Dec. 7, 2020

(51) Int. Cl. G11C 11/16; H01L 43/08; H01L 43/10; H01L 43/02; H01L 27/22

(52) U.S. Cl. CPC G11C 11/161; H01L 43/08; H01L 27/222; H01L 43/02; H01L 43/10

(57) ABSTRACT

An apparatus comprising a magnetic tunnel junction (MTJ), a diffusion barrier, wherein the MTJ is located on the diffusion barrier and a bottom contact that includes a magnetic field generating component, wherein the diffusion barrier is located on top of the bottom contact, wherein the magnetic field generated by the magnetic field generating component affects the stability of the MTJ.

### BACKGROUND

The present invention relates generally to the field of magnetic tunnel junctions (MTJ), and more particularly to applying a magnetic field to the MTJ to control the stability of the free layer.

A Magnetic Tunnel Junction (MTJ) is usually comprised of a free layer, a first reference layer, and a second reference layer. The balancing between the first reference layer (RL1) and the second reference layer (RL2) sometimes is very challenging and is being carried out by controlling the thickness of the layers down to a few angstroms.

### BRIEF SUMMARY

Additional aspects and/or advantages will be set forth in part in the description which follows and, in part, will be apparent from the description, or may be learned by practice of the invention.

An apparatus comprising a magnetic tunnel junction (MTJ), a diffusion barrier, wherein the MTJ is located on the diffusion barrier and a bottom contact that includes a magnetic field generating component, wherein the diffusion barrier is located on top of the bottom contact, wherein the magnetic field generated by the magnetic field generating component affects the stability of the MTJ.

In accordance with an aspect of the present invention, wherein the magnetic field generating component is a magnetic liner.

In accordance with an aspect of the present invention, wherein the magnetic liner is located on sides and bottom of the bottom contact.

In accordance with an aspect of the present invention, wherein magnetic liner has a positive polarity and a negative polarity, wherein the positive polarity can be located on the outside surface of the magnetic liner or on the inside surface of the magnetic liner, wherein the negative polarity is located on a surface magnetic liner opposite of the positive polarity.

In accordance with an aspect of the present invention, wherein the magnetic liner generates two magnetic fields centered at each end of the magnetic liner in contact with the diffusion barrier.

In accordance with an aspect of the present invention, wherein each end of the magnetic liner needs to less than 100 nm away from the MTJ.

In accordance with an aspect of the present invention, wherein a material of the magnetic liner can be selected from a group that includes Co, Ni, or ferromagnetic materials.

In accordance with an aspect of the present invention, wherein the MTJ includes a free layer, wherein the generated magnetic field affects the stability of the free layer in the MTJ.

In accordance with an aspect of the present invention, wherein the magnetic liner has a polarity such that the generated magnetic field extends from a first end of the liner on one side of the bottom contact to a second end of the liner located on another side of the bottom contact.

In accordance with an aspect of the present invention, wherein each end of the magnetic liner needs to in the range of 20-50× the thickness of the magnetic liner away from the MTJ.

In accordance with an aspect of the present invention, wherein a material of the magnetic liner can be selected from a group that includes Co, Ni, or ferromagnetic materials.

In accordance with an aspect of the present invention, wherein the MTJ includes a free layer, wherein the generated magnetic field affects the stability of the free layer in the MTJ.

In accordance with an aspect of the present invention, wherein the bottom contact is comprised of a magnet material or the bottom contact is comprised of metal doped with a magnetic material.

In accordance with an aspect of the present invention, wherein the bottom contact as a first polarity at side in contact with the diffusion barrier and the bottom contact has a second polarity on the side farthest from the diffusion barrier, wherein the first polarity is the opposite polarity of the second polarity.

In accordance with an aspect of the present invention, wherein the bottom contact generates a first magnetic field that extends from the bottom of a first side of the bottom contact to top of the first side of the bottom contact and the bottom contact generates a second magnetic field that extends from the bottom of a second side of the bottom contact to top of the second side of the bottom contact.

In accordance with an aspect of the present invention, wherein the MTJ includes a free layer, wherein the generated the first magnetic field and the second magnetic affects the stability of the free layer in the MTJ.

In accordance with an aspect of the present invention, wherein the bottom contact as a positive polarity at a first horizontal end of bottom contact and the bottom contact has a negative polarity on a second horizontal end bottom contact, wherein the first horizontal end and second horizontal end are at opposite ends of the bottom contact.

In accordance with an aspect of the present invention, wherein the bottom contact generates a first magnetic field that extends from the top of a first horizontal end of the bottom contact to top of the second horizontal end of the bottom contact and the bottom contact generates a second magnetic field that extends from the bottom of first horizontal end of the bottom contact to the bottom of the second horizontal end of the bottom contact.

In accordance with an aspect of the present invention, wherein the MTJ includes a free layer, wherein the generated the first magnetic field affects the stability of the free layer in the MTJ.

In accordance with an aspect of the present invention, wherein the magnetic material of bottom contact or the magnet doping material can be selected from a group that includes Co, Ni, or ferromagnetic materials.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross section of a MRAM device having a MTJ, in accordance with an embodiment of the present invention.

FIG. 2 illustrates a cross section of a MRAM device having a MTJ, in accordance with an embodiment of the present invention.

FIG. 3 illustrates a cross section of a MRAM device having a MTJ, in accordance with an embodiment of the present invention.

FIG. 4 illustrates a cross section of a MRAM device having a MTJ, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e. two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various process used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g. aluminum, copper, etc.) and insulators (e.g. various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, wherein like reference numerals refer to like elements throughout. Embodiments of the present invention are generally directed to a MRAM that include a magnetic tunnel junction (MTJ). A MTJ consists of two layers of magnetic metal, such as cobalt iron, separated by an ultrathin layer of insulator, typically aluminum oxide with a thickness of about 1 nm. The insulating layer is so thin that electrons can tunnel through the barrier if a bias voltage is applied between the two metal electrodes. In MTJs the tunneling current depends on the relative orientation of magnetizations of the two ferromagnetic layers, which can be changed by an applied magnetic field. MTJs that are based on transition-metal ferromagnets and Al₂O₃ barriers can be fabricated with reproducible characteristics and with TMR values up to 50% at room temperature. Recently in crystalline MTJs with MgO barriers large values of TMR have been observed further boosting interest in spin dependent tunneling.

MRAM device includes a top contact, a metal hard mask, a MTJ, a diffusion barrier, and a bottom contact. The present invention modifies the bottom contact to include a magnetic material, for example, Co, Ni, ferromagnetic materials, or other magnetic material. The magnetic material in the bottom contact generates a magnetic field that is large enough to affect the free layer of the MTJ. The magnetic field stabilizes the free layer, thus improving the memory stability of the MTJ in the MRAM.

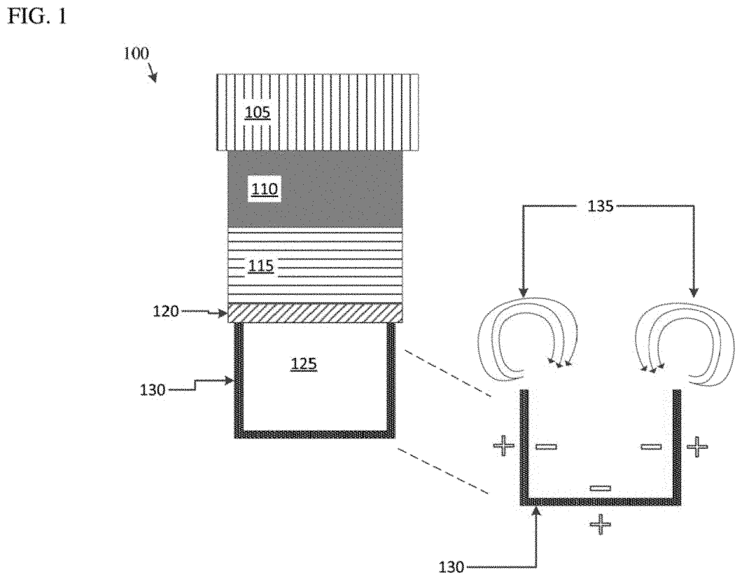

FIG. 1 illustrates a cross section of a MRAM device 100 having an MTJ, in accordance with an embodiment of the present invention. The MRAM device 100 includes a top contact 105, a metal hard mask 110, a MTJ 115, a diffusion barrier 120, a bottom contact 125, and a magnetic liner 130. The MTJ 115 is comprised of a first reference layer (RL1) (not shown), a second reference layer (RL2) (not shown), and a free layer (FL) (not shown). The diffusion barrier 120 can be for example, TaN, but the diffusion barrier 120 can be any type of material that can prevent the migration of metal from the bottom contact 125 into the MTJ 115. The magnetic liner 130 lines the outer surface of the bottom contact 125, such that the magnetic liner 130 is located on the sides and the bottom of the bottom contact 125. The magnetic liner 130 generates a magnetic field 135, where the magnetic field 135 affects the FL of the MTJ 115. For example, the magnetic liner 130 can have a positive polarity located on the outside surface of the magnetic liner 130 and the magnetic liner 130 has a negative polarity located on the inside surface of the magnetic liner 130, as illustrated by the blow up image of FIG. 1. Alternatively, the magnetic liner 130 can have a positive polarity located on inside surface of the magnetic liner 130 and the magnetic liner 130 has a negative polarity located on the outside surface of the magnetic liner 130. This alternative polarity arrangement is similar to the polarity arrangement as shown in FIG. 1, but instead has the polarity being located on opposite surfaces than shown in FIG. 1. The magnetic liner 130 generates two magnetic fields 135 centered at each end of the magnetic liner 130. The shape, materials, and polarity alignment of the magnetic liner 130 affects the size and strength of the generated magnetic field 135. Furthermore, the shape, materials, and polarity alignment of the magnetic liner 130 affects how far the magnetic liner 130 needs to be from the MTJ 115. For example, the magnetic liner 130 as illustrated by FIG. 1, needs to be less than 100 nm away from the MTJ 115, for the magnetic field 135 to be able to affect the FL. The magnetic material of the magnetic liner 130 can be selected from a group that includes Co, Ni, ferromagnetic materials, or other magnetic materials that can generate a sufficient magnetic field 135 to affect the FL. The magnetic field 135 interaction with the free layer (FL) affects the stability of the MTJ 130.

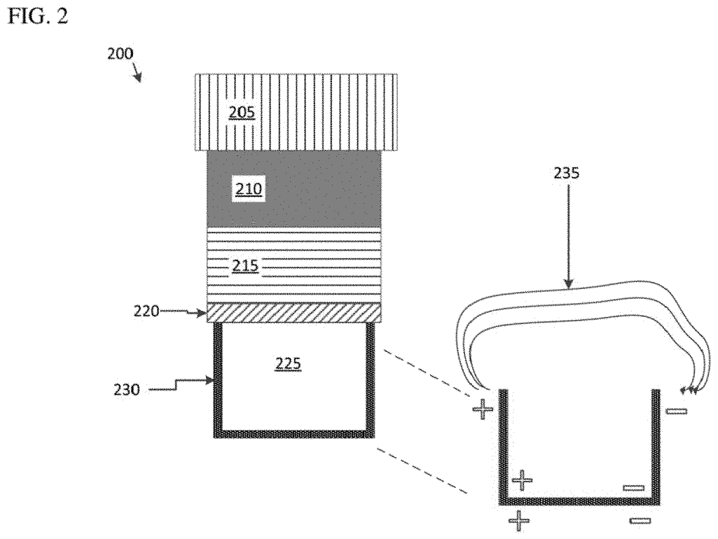

FIG. 2 illustrates a cross section of a MRAM device 200 having an MTJ, in accordance with an embodiment of the present invention. The MRAM device 200 includes a top contact 205, a metal hard mask 210, a MTJ 215, a diffusion barrier 220, a bottom contact 225, and a magnetic liner 230. The MRAM device 200 has the same design as MRAM device 100, but the polarity of the magnetic liner 230 is different than the polarity of the magnetic liner 130 of FIG. 1. The magnetic field 235 generated by magnetic liner 230 is different than the magnetic field 135 generated by magnetic liner 130. The polarity of the magnetic liner 230 allows for one magnetic field 235 to be generated, such that, the magnetic field spans across two ends of the magnetic liner 230. For the generated magnetic field 235 to be able to affect the free layer (FL) of the MTJ 215 then the magnetic liner 230 needs to be in the range of 20-50× the thickness of the magnetic liner 230 away from the MTJ 215. The magnetic material of the magnetic liner 230 can be selected from a group that includes Co, Ni, ferromagnetic materials, or other magnetic materials that can generate a sufficient magnetic field 235 to affect the FL. The magnetic field 235 interaction with the free layer (FL) affects the stability of the MTJ 230.

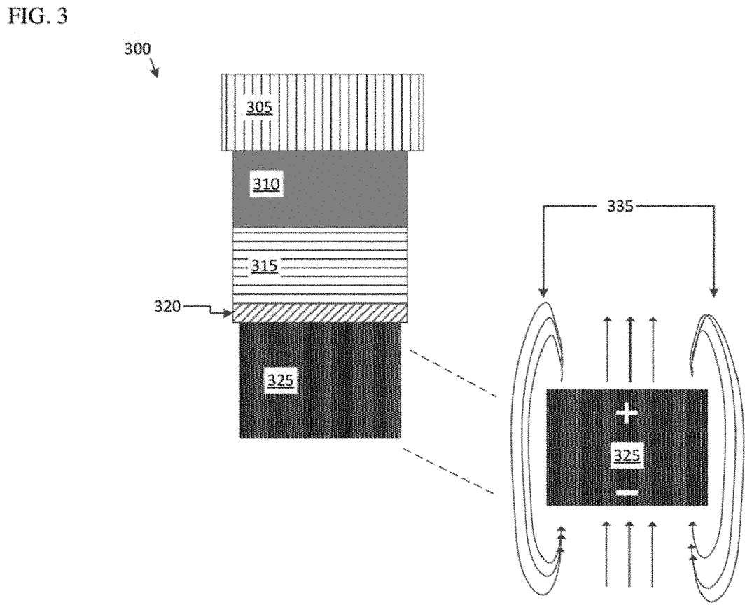

FIG. 3 illustrates a cross section of a MRAM device 300 having an MTJ, in accordance with an embodiment of the present invention. The MRAM device 300 includes a top contact 305, a metal hard mask 310, a MTJ 315, a diffusion barrier 320, a magnetic bottom contact 325. The MRAM device 300 is similar to the MRAM device 100, but the magnetic bottom contact 325 has replaced the bottom contact 125 and the magnetic liner 130. The magnetic bottom contact 325 can be comprised of a magnetic material or it can be a conductive material that has been doped with a magnetic material. As illustrated by FIG. 3, the magnetic bottom contact 325 has a positive polarity on the side adjacent to the diffusion barrier 320 and a negative polarity on the side farthest from the diffusion barrier 320. Alternatively, the magnetic bottom contact 325 can have a negative polarity on the side adjacent to the diffusion barrier 320 and a positive polarity on the side farthest from the diffusion barrier 320. The magnetic bottom contact 325 generates a magnetic field 335 at each end of the magnetic bottom contact 325, such that each magnetic field 335 affects the free layer of the MTJ 315. The magnetic material of the magnetic bottom contact 325 can be selected from a group that includes Co, Ni, ferromagnetic materials, or other magnetic materials that can generate a sufficient magnetic field 335 to affect the FL. The magnetic bottom contact 325 needs to be in the range of 20-50× the thickness of the magnetic bottom contact 325 away from the MTJ 315 to be able to affect the free layer of the MTJ 215. The magnetic field 335 interaction with the free layer (FL) affects the stability of the MTJ 330.

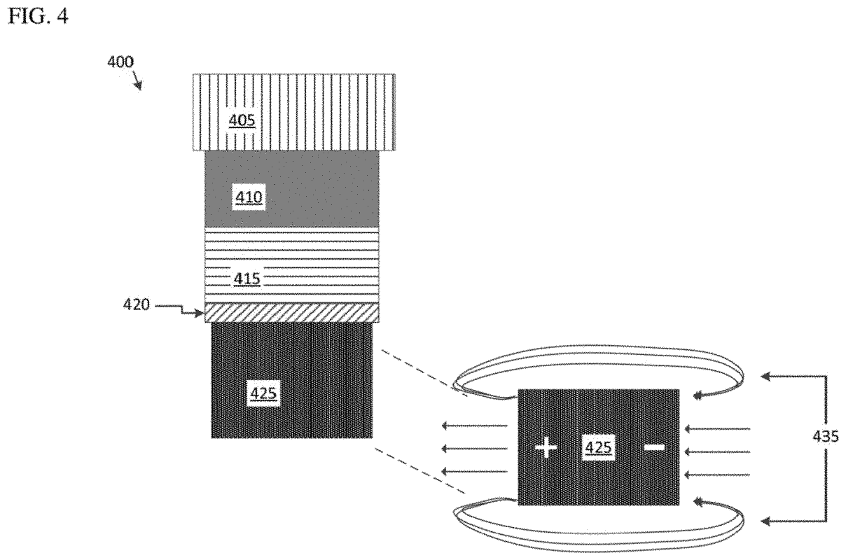

FIG. 4 illustrates a cross section of a MRAM device 400 having an MTJ, in accordance with an embodiment of the present invention. The MRAM device 400 includes a top contact 405, a metal hard mask 410, a MTJ 415, a diffusion barrier 420, a magnetic bottom contact 425. The MRAM device 400 has the same design as MRAM device 300, but the polarity of the magnetic bottom contact 425 is different than the polarity of magnetic bottom contact 325 of FIG. 3. The magnetic field 435 generated by magnetic bottom contact 425 is different than the magnetic field 335 generated by magnetic bottom contact 325. The magnetic bottom contact 425 has a positive polarity on one horizontal end of the magnetic bottom contact 425 and a negative polarity on opposite horizontal end of the magnetic bottom contact 425. The magnetic bottom contact 425 generates a magnetic field 435 along the horizontal surfaces of the magnetic bottom contact 425, such that only one of the two generated magnetic fields 435 affects the free layer of the MTJ 415. The magnetic material of the magnetic bottom contact 425 can be selected from a group that includes Co, Ni, ferromagnetic materials, or other magnetic materials that can generate a sufficient magnetic field 435 to affect the FL. The magnetic field 435 interaction with the free layer (FL) affects the stability of the MTJ 430.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. An apparatus comprising:
a magnetic tunnel junction (MTJ);
a diffusion barrier, wherein the MTJ is located on the diffusion barrier; and
a bottom contact that includes a magnetic field generating component, wherein the diffusion barrier is located on top of the bottom contact, wherein the magnetic field generated by the magnetic field generating component affects the stability of the MTJ.

2. The apparatus of claim 1, wherein the magnetic field generating component is a magnetic liner.

3. The apparatus of claim 2, wherein the magnetic liner is located on sides and bottom of the bottom contact.

4. The apparatus of claim 3, wherein magnetic liner has a positive polarity and a negative polarity, wherein the positive polarity can be located on the outside surface of the magnetic liner or on the inside surface of the magnetic liner, wherein the negative polarity is located on a surface magnetic liner opposite of the positive polarity.

5. The apparatus of claim 4, wherein the magnetic liner generates two magnetic fields centered at each end of the magnetic liner in contact with the diffusion barrier.

6. The apparatus of claim 4, wherein each end of the magnetic liner needs to less than 100 nm away from the MTJ.

7. The apparatus of claim 6, wherein a material of the magnetic liner can be selected from a group that includes Co, Ni, or ferromagnetic materials.

8. The apparatus of claim 6, wherein the MTJ includes a free layer, wherein the generated magnetic field affects the stability of the free layer in the MTJ.

9. The apparatus of claim 3, wherein the magnetic liner has a polarity such that the generated magnetic field extends from a first end of the liner on one side of the bottom contact to a second end of the liner located on another side of the bottom contact.

10. The apparatus of claim 9, wherein each end of the magnetic liner needs to in the range of 20-50× the thickness of the magnetic liner away from the MTJ.

11. The apparatus of claim 10, wherein a material of the magnetic liner can be selected from a group that includes Co, Ni, or ferromagnetic materials.

12. The apparatus of claim 11, wherein the MTJ includes a free layer, wherein the generated magnetic field affects the stability of the free layer in the MTJ.

13. The apparatus of claim 1, wherein the bottom contact is comprised of a magnet material or the bottom contact is comprised of metal doped with a magnetic material.

14. The apparatus of claim 13, wherein the bottom contact as a first polarity at side in contact with the diffusion barrier and the bottom contact has a second polarity on the side farthest from the diffusion barrier, wherein the first polarity is the opposite polarity of the second polarity.

15. The apparatus of claim 14, wherein the bottom contact generates a first magnetic field that extends from the bottom of a first side of the bottom contact to top of the first side of the bottom contact and the bottom contact generates a second magnetic field that extends from the bottom of a second side of the bottom contact to top of the second side of the bottom contact.

16. The apparatus of claim 15, wherein the MTJ includes a free layer, wherein the generated the first magnetic field and the second magnetic affects the stability of the free layer in the MTJ.

17. The apparatus of claim 13, wherein the bottom contact as a positive polarity at a first horizontal end of bottom contact and the bottom contact has a negative polarity on a second horizontal end bottom contact, wherein the first horizontal end and second horizontal end are at opposite ends of the bottom contact.

18. The apparatus of claim 17, wherein the bottom contact generates a first magnetic field that extends from the top of a first horizontal end of the bottom contact to top of the second horizontal end of the bottom contact and the bottom contact generates a second magnetic field that extends from the bottom of first horizontal end of the bottom contact to the bottom of the second horizontal end of the bottom contact.

19. The apparatus of claim 18, wherein the MTJ includes a free layer, wherein the generated the first magnetic field affects the stability of the free layer in the MTJ.

20. The apparatus of claim 13, wherein the magnetic material of bottom contact or the magnet doping material can be selected from a group that includes Co, Ni, or ferromagnetic materials.
